(19) United States
(12) Patent Application Publication
(10) Pub. No.: US 2017/0003463 A1
(43) Pub. Date: Jan. 5, 2017

(54) PASSIVE PLACEMENT OF A LASER ON A PHOTONIC CHIP

(71) Applicant: Cisco Technology, Inc., San Jose, CA (US)

(72) Inventors: Mary NADEAU, Alburtis, PA (US); Thomas DAUGHERTY, Allentown, PA (US); Ravi Sekhar TUMMIDI, Breinigsville, PA (US); Vipulkumar PATEL, Breinigsville, PA (US)

(21) Appl. No.: 14/790,925

(22) Filed: Jul. 2, 2015

(51) Int. Cl. G02B 6/42; H01S 5/022; H01S 5/02; G02B 6/13

(52) U.S. Cl. CPC G02B 6/4232; G02B 6/13; G02B 6/4238; H01S 5/02272; H01S 5/0216; H01S 5/02276; H01S 5/021

(57) ABSTRACT

Embodiments disclosed herein generally relate to a method for manufacturing a photonic device that facilitates precise alignment of a laser with a waveguide. The method generally includes disposing the laser on a support member on a substrate such that the laser contacts the support member. The support member may extend in a direction perpendicular to a base plane of the substrate, and solder may be disposed on the base plane such that a height of the solder in the direction perpendicular to the base plane is less than a height of the support member so that a gap is created between the solder and the laser. Once the laser has been properly aligned with the waveguide, the solder may be heated (e.g., reflowed) so that the solder contacts the laser.

### TECHNICAL FIELD

Embodiments presented herein generally relate to waveguides in a photonic device, and more specifically, to accurate placement of a laser.

### BACKGROUND

Silicon-on-Insulator (SOI) optical devices may include an active surface layer that includes waveguides, optical modulators, detectors, complementary metal-oxide-semiconductor (CMOS) circuitry, metal leads for interfacing with external semiconductor chips, and the like. Transmitting optical signals from and to this active surface layer introduces many challenges. In some optical devices, lenses are used to focus the light from an external fiber optic cable or a laser source into the waveguides, thereby shrinking the mode or adjusting the numerical aperture such that the optical signal can be efficiently transferred into the sub-micron waveguides.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a block diagram of a silicon photonic chip with a laser optically coupled with a waveguide, according to certain embodiments of the present disclosure.

FIG. 2 is a flow diagram of example operations for manufacturing a photonic device, according to certain embodiments of the present disclosure.

FIG. 3 illustrates a photonic device comprising a waveguide and support members to optically couple a laser with the waveguide, according to certain embodiments of the present disclosure.

FIG. 4 illustrates alignment of a laser with a waveguide of a photonic chip, according to certain embodiments of the present disclosure.

FIG. 5 illustrates the photonic device of FIG. 3 where a laser is disposed on the support members and aligned with the waveguide, according to certain embodiments of the present disclosure.

FIG. 6A illustrates a photonic device comprising a laser and solder prior to being reflowed, according to certain embodiments of the present disclosure.

FIG. 6B illustrates the photonic device of FIG. 6A after the solder has been reflowed, according to certain embodiments of the present disclosure.

FIGS. 7A-7D are surface profiles and cross sectional views of a photonic device prior to and after a solder reflow process, according to certain embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DESCRIPTION OF EXAMPLE EMBODIMENTS

### Overview

One embodiment presented in this disclosure is a method. The method generally includes disposing a bottom surface of a laser on a support member, wherein the support member is formed on a substrate and extends in a direction perpendicular to a base plane of the substrate, wherein the bottom surface of the laser is in a facing relationship with the base plane, and wherein solder is disposed on the base plane such that a height of the solder in the direction perpendicular to the base plane is less than a height of the support member so that a gap is created between the solder and the laser; aligning the laser with an optical waveguide; and heating the solder, after the alignment of the laser with the optical waveguide, so that the solder contacts the laser.

Another embodiment presented herein is a photonic chip. The photonic chip generally includes a substrate defining a base plane, a support member extending from the base plane wherein a height of the support member relative to the base plane is selected to provide alignment of a laser when mounted on the chip in at least one direction. The photonic chip further includes solder disposed on the base plane, wherein a height of the solder relative to the base plane is less than the height of the support member relative to the base plane; and an optical waveguide configured to receive an optical signal from the laser when mounted on the photonic chip.

Another embodiment presented herein is a method. The method generally includes mating a first surface of a laser with a second surface of a support member, wherein the support member extends from a base plane of a substrate and wherein the first surface and the base plane are in a spaced, facing relationship to one another to form an interstitial gap, and wherein solder is disposed in the interstitial gap, and wherein the solder has a thickness that is less than the interstitial gap; aligning the laser with an optical waveguide; and after the alignment, heating the solder so that the solder is reflowed into contact with one of the first surface of the laser and the base plane of the substrate.

### Example Embodiments

The cost of optical transceivers is greatly influenced by the cost of packaging. The packaging cost is often driven by the process used to attach and actively align a semiconductor laser with a waveguide to achieve high precision and tight tolerances. Because precise placement and alignment of a laser with a waveguide may be difficult, alignment may be achieved using micro-optics (e.g., silicon lenses on the order of 100 to 200 microns in diameter) and an active alignment technique. However, using lenses increases the cost and complexity of the optical device. Moreover, the lenses need to be aligned to ensure the signal from the light-carrying medium or from a light generating device focuses onto the waveguide. As such, not only do the lenses add cost to an optical system, but coupling efficiency suffers if the lenses are not aligned correctly.

The approach used to attach and align the laser can greatly influence the overall cost of optical transceivers as well as the cost of manufacturing equipment, overall quality, yield, and manufacturability. There is also rising demand for cheaper and more compact solution which is primarily driven by the growth of data centers. Therefore, there is a need for a packaging scheme which allows for precise passive placement and alignment of a laser resulting in good coupling efficiency, even in the absence of micro-optics.

Embodiments of the present disclosure provide a packaging method involving the use of lithographically defined features and solder to achieve passive, high precision alignment of a laser component on a silicon photonic chip, sub-mount, or wafer. For example, the packaging methods disclosed herein allow for precise alignment of a laser, using alignment markings, prior to the laser making contact with material (e.g., solder) used for bonding the laser to a photonic chip. The laser may be disposed on a support member of the photonic chip, where a height of the support member is finely tuned for precise alignment of the laser in a vertical direction with a waveguide formed in the photonic chip. As used herein, the term disposed does not necessarily mean contacting. That is, the laser may be disposed on the support member, even though other intermediary layers of material may be between the laser and the support member. Alignment markings may be used to laterally align the laser with the waveguide. Once the laser has been properly aligned with the waveguide, solder may be reflowed such that the solder contacts the laser. By precisely aligning the laser with the waveguide prior to the solder making contact with the laser, laser alignment precision is improved.

Precise placement and alignment of the laser allows for butt-coupling of the laser to a silicon photonic system (e.g., a silicon waveguide). That is, the laser may be directly coupled with the waveguide such that light is transferred between the laser and the waveguide without the use of lenses. The technique can be used on a single die or at wafer scale assembly and allows volume manufacturing with significant cost reduction.

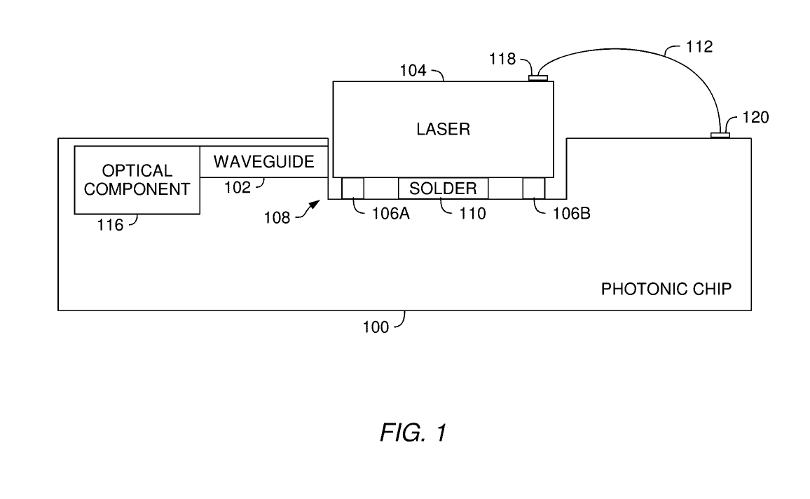

FIG. 1 illustrates a photonic chip 100 (e.g., an optical device) which includes a waveguide 102 and a laser 104 that is directly coupled (e.g., butt-coupled) to the waveguide 102. As illustrated, the laser 104 may be supported by vertical stops (e.g., support members 106A and 106B) that extend in a direction perpendicular to a surface 108 of the photonic chip 100. The laser may be bonded to the photonic chip 100 with the use of solder 110 that may be disposed on the surface 108. The solder 110 may be used to form a mechanical connection, or a mechanical and electrical connection between the photonic chip 100 and the laser 104. For example, the laser 104 may be powered by a circuit of the photonic chip 100 either through the solder 110, or via a wire bond 112 that is connected to the top of the laser, or both. The wire bond may be bonded to the laser 104 via a bond pad 118 and coupled to the circuit of the photonic chip 100 through a bond pad 120. The wire bond 112 connected to the top of the laser 104 and the solder 110 together may create an electrical path to power the laser. For example, the photonic chip may drive different voltages and electrical currents on the wire bond and solder 110 in order to control the output of the laser 104. During operation, the laser 104 directs light into the waveguide 102, which may be coupled with one or more optical components 116. For example, the light from the laser 104 may be guided by the waveguide 102 to an optical modulator (e.g., a Mach-Zehnder modulator, a total-internal-reflection (TIR)-based structures, ring resonators and Fabry-Perot resonators) that modulates the optical signal for data transmission, an optical splitter, phase adjustment element, etc.

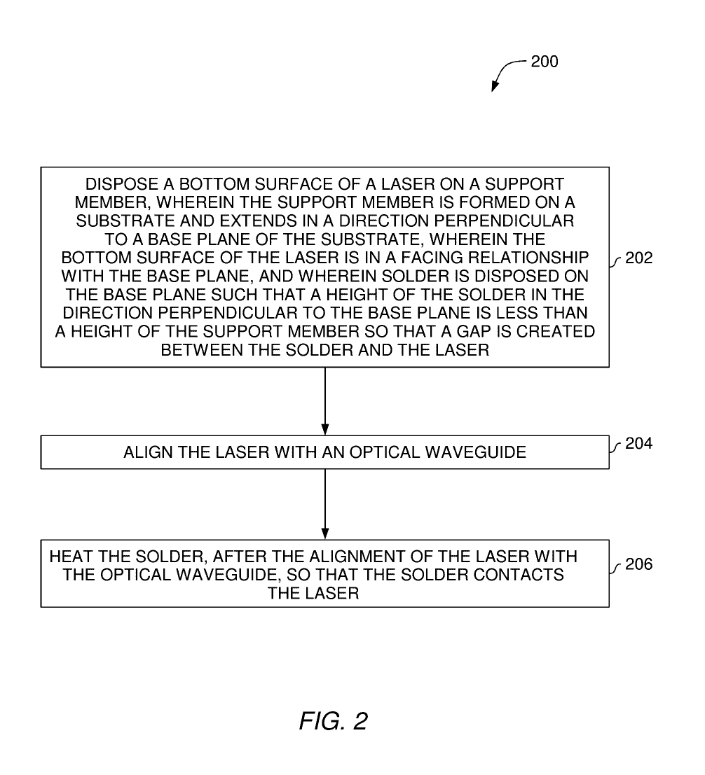

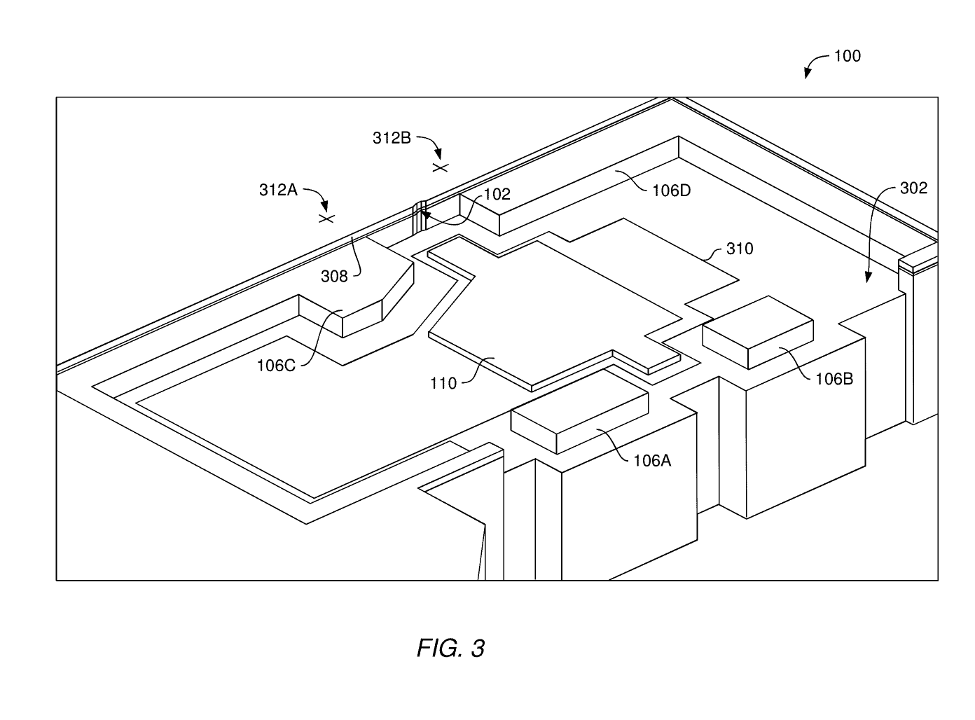

FIG. 2 illustrates example operations 200 for manufacturing or assembling a photonic device (e.g., photonic chip 100), according to certain embodiments of the present disclosure. For clarity, the different operations 200 in FIG. 2 are discussed with corresponding structures shown in FIGS. 3-5.

The operations 200 generally include, at block 202, disposing a bottom surface of a laser (e.g., laser 104) on a support member such that the laser 104 is disposed on the support member 106. In certain embodiments, the support member may be formed on a substrate. For example, the support member may be part of the substrate to form a single monolithic structure. In other embodiments, the support member and the substrate may be two separate structures that have been attached together. As illustrated in FIG. 3, a bottom surface of the laser is in a facing relationship with the base plane 302. Solder 110 is disposed on the base plane 302 such that a height of the solder 110 in the direction perpendicular to the base plane 302 is less than a height of the support member so that a gap is created between the solder 110 and the laser (not shown). In certain embodiments, the solder may be disposed on an electrode layer 310 that is on the base plane 302.

Generally, FIG. 3 illustrates a photonic chip 100 comprising a substrate 302, waveguide 102 and pedestals (e.g., support members 106A, 106B, 106C, and 106D (collectively 106)) for supporting the laser that may be butt-coupled with the waveguide 102 (buried in the layers), according to certain embodiments of the present disclosure. As illustrated, the support members 106 may be part of the substrate 302 and comprise of the same material. Alternatively, the support members 106 may be a different material than the substrate 302. In certain embodiments, the substrate 302 may comprise a crystalline semiconductor like silicon, an oxide or another kind of dielectric.

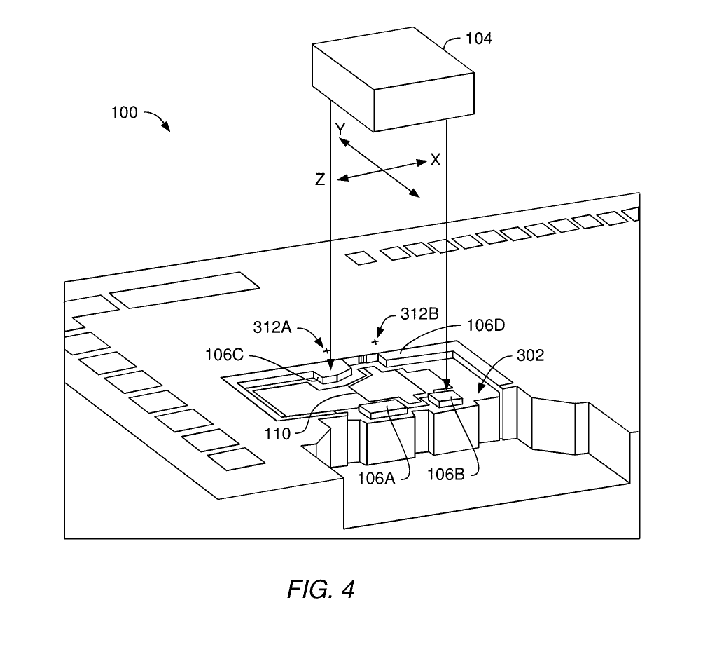

The support members 106 may be lithographically defined using standard complementary metal-oxide-semiconductor (CMOS) and/or silicon micro-electro-mechanical systems (MEMs) processes which allow for precise control of the height of the support members 106. The height of the support members 106 are determined such that, upon placement of the laser on the support members 106, the laser is aligned with the waveguide 102 in the vertical direction. Thus, the support members 106 are accurate reference surfaces of the substrate 302 such that when the bottom surface of the laser is disposed directly on the support members 106, the precise location of the laser relative to the waveguide 102 in the vertical direction (e.g., z direction as illustrated in FIG. 4) is set.

The photonic chip 100 also includes a stack of layers 308 (e.g., formed on top of the substrate 302) which includes a silicon layer which contains the waveguide 102. In certain embodiments, the stack of layers 308 may be an inter-layer dielectric (ILD). Solder 110 is disposed on the substrate 302 such that a height (i.e., the z direction) of the solder 110 above the substrate 302 is less than the height of the support members 106 above the substrate 302. Therefore, a gap exists between the top of the solder 110 and the bottom of the laser when the laser is disposed on top of the support members 106. This gap allows for precise alignment of a laser 104 (e.g., to be disposed on the support members 106) with the waveguide 102, as will be described in more detail with respect to FIGS. 4-7.

In the embodiment shown, an electrode layer 310 is disposed between the substrate 302 and the solder 110. The electrode layer 310 may be used to make an electrical connection with the solder. That is, when the laser is disposed on the support members 106 and solder 110 is reflowed and makes contact with the laser, the electrode layer 310 may be used for powering the laser via a circuit of the photonic chip 100. For example the circuit of the photonic chip may be wire bonded to the electrode layer 310 using a bond pad on the top surface of the substrate to form an electrical contact with the solder 110.

Moreover, the waveguide 102 includes an interface that is substantially perpendicular to a base plane of the substrate 302 from which the support members 106 extend. As used herein, “substantially perpendicular” means the interface and the base plane may not be precisely perpendicular given the limitations of fabrication techniques used to generate these features. Thus, these surfaces may be up to 5-10 degrees off from being perpendicular.

Returning to the operations 200 of FIG. 2, at block 204, the laser is aligned with an optical waveguide. For example, the photonic chip 100 may include one or more lithographically defined features, such as the alignment markings 312A and 312B (collectively 312), as illustrated in FIG. 3. The alignment markings 312 may be used during an alignment process of the laser with the waveguide 102, as described in more detail with respect to FIG. 4.

FIG. 4 illustrates aligning laser 104 with the waveguide 102 of the photonic chip 100, according to certain embodiments of the present disclosure. As illustrated, the laser 104 in the optical system can be precisely aligned in the X, Y, and Z directions on the support members 106 before being attached to the substrate 302. In this example, the attach material is a solder connection (e.g., solder 110) that provides electrical, thermal, and mechanical contact between the substrate 302 (or an electrode 310 disposed on the substrate 302) and the laser 104. Accurate placement and attachment of the laser 104 on the photonic chip 100 (e.g., on support members 106) allows the laser's optical output to be directly coupled to the waveguide 102 without lenses or active feedback (referred to as passive butt coupling).

In certain embodiments, the laser 104 and the silicon photonic substrate both have lithographically defined and etched features (e.g., alignment markings) which allow vision based passive alignment along the X and Y axes. Moreover, as described above, the height of the support members 106 are determined such that, upon placement of the laser 104 on the support members 106, the laser 104 is aligned with the waveguide 102 in the vertical direction (e.g., z direction as illustrated).

If the solder 110 has a height above the substrate 302 that is greater than the height of support members 106 above the substrate 302, the laser 104 and the solder 110 may be in physical contact before the solder 110 is reflowed during the heating process. This may result in a gap between support members 106 of the photonic chip and laser (more specifically, the bottom surface of the laser 104 and the top surface of the support members 106) prior to the solder reflow process. As a result, the bonding equipment may first align the components in two axes (X and Y axes) and subsequently allow the laser 104 to travel in the Z direction while the solder is being reflowed (e.g., until the laser makes contact with support members 106). However, as the laser 104 moves in the Z direction to make contact with the support members 106 (e.g., by applying pressure on the laser 104 in the z direction), the alignment of the laser 104 and the waveguide 102 in the X and Y axes may be lost. In other words, it is difficult to maintain laser alignment in the X and Y axes while the laser moves in a downward direction towards the support members 106 and pushes against the reflowed solder 110. To avoid this problem, the embodiments herein form the solder 110 on the substrate 302 such that a gap exists, prior to the solder 110 being reflowed, between the laser 104 and the solder 110 when the vertical stops (e.g., support members 106) are in contact with the laser 104. For example, while resting on the support members 106 (which passively aligns the laser in the Z direction), the laser can be adjusted in the X and Y direction using, e.g., the alignment marks 312. Once aligned in the X, Y, and Z directions, pressure may be applied in the downward direction to maintain the alignment when the solder is reflowed. In this manner, placement of the laser 104 on the support members 106 without making contact with the solder 110 allows for precise alignment in X, Y, and Z directions before the solder 110 is reflowed.

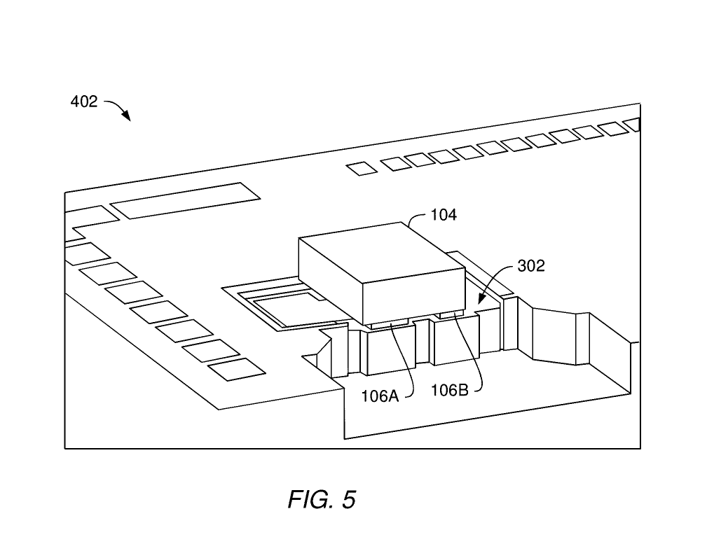

FIG. 5 illustrates the photonic chip 100 with the laser 104 in contact with the support member 106, according to certain embodiments of the present disclosure. Once the laser 104 is placed on the support members 106 as illustrated, the process of attaching the solder 110 with the laser 104 may be completed by heating the solder 110. For example, returning to FIG. 2, at block 206, after the alignment of the laser with the optical waveguide, the solder may be heated (e.g., reflowed) so that the solder contacts the laser. As the solder is reflowed, the solder may rise (e.g., dome up such that the height of the solder increases) and close the gap between the solder and the laser 104.

In certain embodiments, once the laser 104 and the waveguide 102 have been aligned, pressure may be applied to the laser 104 towards the support members 106 to prevent misalignment of the laser 104 with the waveguide 102 during the solder reflow process. In certain embodiments, the solder may be heated during the solder reflow process through the substrate 302. That is, heat may be applied (e.g., via another laser not shown) to a bottom portion of the substrate 302 until the heat is transferred to the solder and the solder is reflowed. In this embodiment, the laser that heats the solder emits light that can propagate through the material of the substrate until it strikes the solder. As such, this laser may be disposed beneath the bottom of the photonic chip. However, disposing the laser such that it emits light that strikes the solder in the z direction is not a requirement. In other embodiments, the laser can be located at one of the sides of the photonic chip such that the light strikes the solder in the X or Y direction. Moreover, in other embodiments the solder may be reflown using a heat source other than a laser. For example, an electrical current or heating element disposed proximate to the solder in the photonic chip may be used to reflow the solder.

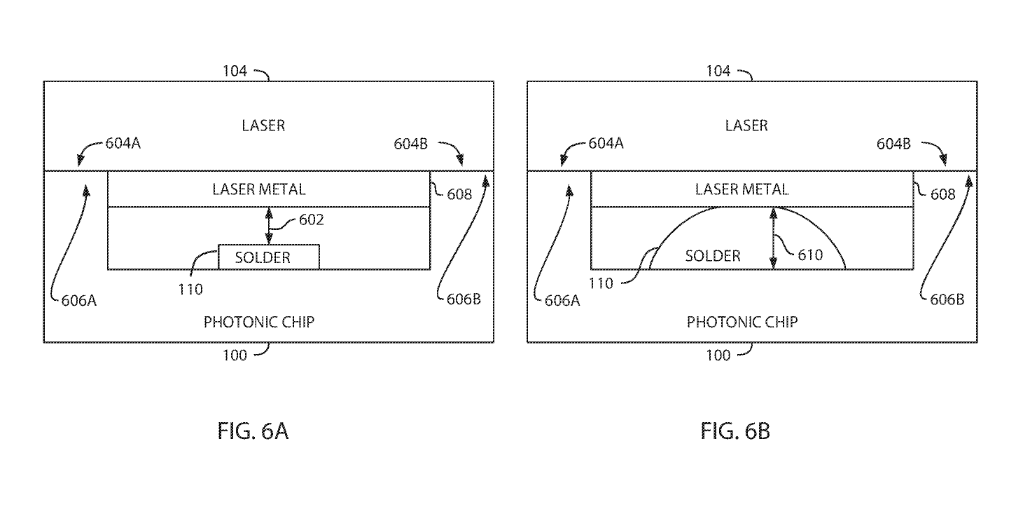

FIGS. 6A and 6B are block diagrams of photonic chip 100 before and after the solder reflow process, according to certain embodiments of the present disclosure. As illustrated in FIG. 6A, and described above, the solder 110 may be disposed on the photonic chip 100 such that a gap 602 exists between the solder 110 and a metal connection 608 of the laser 104. For example, when the laser is disposed on the photonic chip 100, the bottom surface of the laser at 604A and 604B contacts top surfaces of the support members at 606A and 606B, leaving gap 602 between the solder 110 and laser metal 608.

During the reflow process, the solder 110 is heated by a heat source (e.g., another laser) such that the solder 110 liquefies and domes until the solder 110 makes contact with the laser metal 608, as illustrated in FIG. 6B. Thus, because of the natural tendency for the solder 110 to form a dome when liquefied, the thickness of the solder 110 in the middle increases to bridge the gap 602 and make an electrical and mechanical contact between the photonic chip 100 and the laser metal 608 which can be used to power the laser 104. The bond between the photonic chip 100 and the laser metal 608 is completed when the heat source stops heating the solder 110 and the solder 110 cools back into its solid state. The dimensions of the deposited solder can be used to optimize the solder volume for a successful bond between the solder 110 and the laser metal 608. For example, in certain embodiments, a thickness 610 of the solder 110 from the substrate 302 to top of the solder 110 may be about four microns. In certain aspects the gap between the top of the solder and the top of the support members 106 (e.g., defining gap 602) may be between one micron to two microns. In certain embodiments, a width and/or length of the laser 104 may be between 200 to 500 microns and the height of the laser may be about a 100 microns.

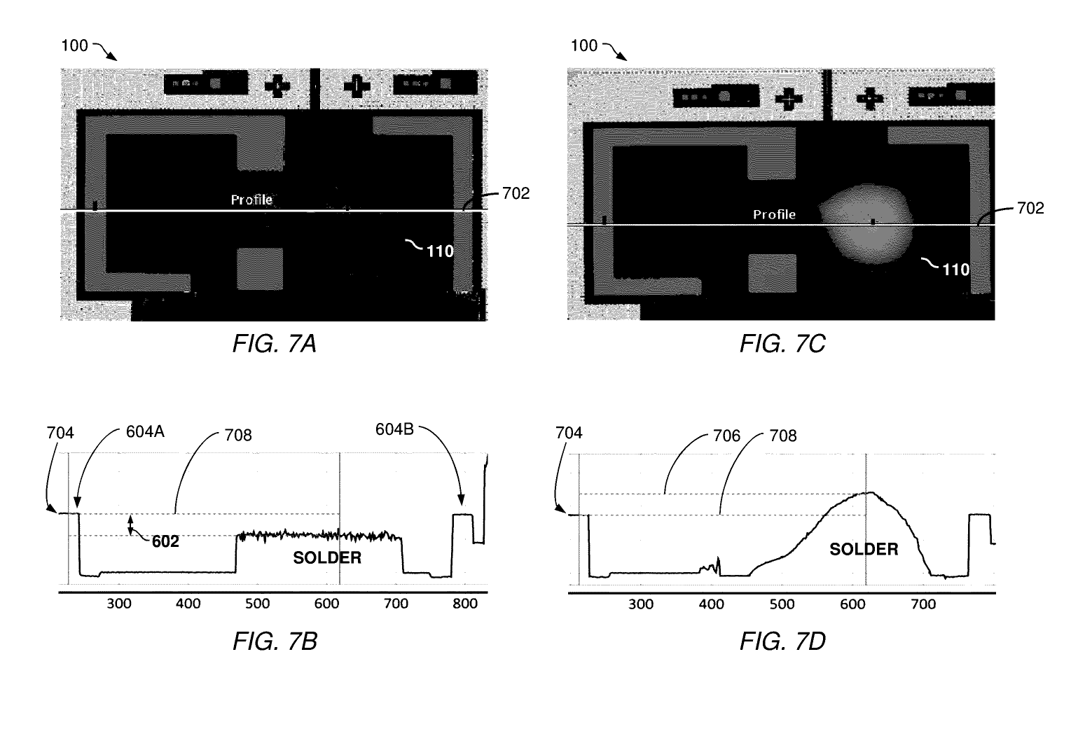

FIGS. 7A-7D are surface profiles, and cross sectional views of a photonic chip 100 prior to and after the solder 110 has been reflowed, according to an embodiment of the present disclosure. FIGS. 7A-7D do not show the laser 104, but instead illustrate the doming characteristics of the reflowed solder in the absence of the laser 104. As illustrated in FIG. 7A, solder 110 may be deposited on a surface of the photonic chip 100 (e.g., surface of an electrode). FIG. 7B illustrates a cross sectional view of the photonic chip across the profile line 702. The cross sectional view illustrated in FIG. 7B shows the height of the solder 110 which can be compared to the height of the support members at 704. As illustrated, the gap 602 exists between the top of the solder 110 and the top of the support members at 704. The gap may be large enough to prevent the solder from contacting the laser metal 608 as illustrated in FIG. 6A. FIG. 7C illustrates the photonic chip 100 after the solder 110 has been reflowed. As illustrated in FIG. 7D, which is a cross sectional view of FIG. 7C across the profile line 702, the height of the solder 110 has increased and has closed the gap 602. That is, the height of the solder 110 demonstrated by line 706 is greater than the height of the support members at 704 demonstrated by line 708. Therefore, when a laser 104 is disposed on the support members 106, the solder 110 may be reflowed such that the solder 110 makes contact with the bottom of the laser. By including the gap 602 as illustrated in FIG. 7B before the solder is reflowed, the laser 104 can be precisely aligned and held in place in not only the X and Y directions, but also the Z direction, prior to the solder reflow process.

While examples of the present disclosure have described solder as being disposed on the substrate to facilitate understanding, persons of ordinary skill in the art understand that the solder may be disposed anywhere in a gap between the laser and the substrate so long as a thickness of the solder is less than the gap. For example, solder may be disposed on a bottom surface of the laser, which can be reflowed into contact with the substrate once the laser has been properly aligned.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

The flowchart and block diagrams in the Figures illustrate the architecture, functionality and operation of possible implementations of systems or methods. It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

In view of the foregoing, the scope of the present disclosure is determined by the claims that follow.

1. A method, comprising:
disposing a bottom surface of a laser on a support member, wherein the support member is formed on a substrate and extends in a direction perpendicular to a base plane of the substrate, wherein the bottom surface of the laser is in a facing relationship with the base plane, and wherein solder is disposed on the base plane such that a height of the solder in the direction perpendicular to the base plane is less than a height of the support member so that a gap is created between the solder and the laser;
aligning the laser with an optical waveguide; and
heating the solder, after the alignment of the laser with the optical waveguide, so that the solder contacts the laser.

2. The method of claim 1, further comprising disposing an electrode between the substrate and the solder, wherein the solder is disposed on the electrode.

3. The method of claim 2, further comprising connecting a trace from a circuit in the substrate to the electrode to provide power to the laser via the solder.

4. The method of claim 1, further comprising applying pressure on the laser towards the support member when heating the solder.

5. The method of claim 1, wherein the substrate is part of a photonic chip, the photonic chip comprising the optical waveguide, the method further comprising creating an alignment marking on the photonic chip, wherein aligning the laser with the optical waveguide comprises aligning the laser using the alignment marking and the support member.

6. The method of claim 5, wherein photonic chip comprises a silicon layer in which the optical waveguide is formed, and wherein the alignment marking is created on the silicon layer.

7. The method of claim 6, wherein creating the alignment marking comprises etching the alignment marking on the silicon layer.

8. The method of claim 6, further comprising creating another alignment marking on the laser, wherein aligning the laser with the optical waveguide comprises aligning the laser using the other alignment marking.

9. The method of claim 1, further comprising forming a wire bond between a circuit in the substrate and the laser, wherein the wire bond and the solder form an electrical path to power the laser.

10. The method of claim 7, wherein the solder connects to the laser on a first side and the wire bond connects to the laser on a second side opposite the first side.

11. The method of claim 10, wherein the solder is located at a top portion of the substrate, and wherein heating the solder comprises applying heat through a bottom portion of the substrate opposite the base plane to reflow the solder.

12-19. (canceled)

20. A method, comprising:
mating a first surface of a laser with a second surface of a support member, wherein the support member extends from a base plane of a substrate and wherein the first surface and the base plane are in a spaced, facing relationship to one another to form an interstitial gap between the first surface and the base plane, and wherein solder is disposed in the interstitial gap, and wherein the solder has a thickness that is less than the interstitial gap;
aligning the laser with an optical waveguide; and
after the aligning, heating the solder so that the solder is reflowed into contact with one of the first surface of the laser and the base plane of the substrate.
